(19) United States
(12) Patent Application Publication
(10) Pub. No.: US 2006/0289304 A1
(43) Pub. Date: Dec. 28, 2006

(54) Sputtering target with slow-sputter layer under target material

(75) Inventors: Raymond M. Mayer, Canton, MI (US); Yiwei Lu, Ann Arbor, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp., Auburn Hills, MI (US)

(21) Appl. No.: 11/158,407

(22) Filed: Jun. 22, 2005

(51) Int. Cl. C23C 14/00

(52) U.S. Cl. 204/298.12

(57) ABSTRACT

Certain example embodiments of this invention relate to a sputtering target(s) for use in sputtering material(s) onto a substrate. In certain example embodiments, the target includes a cathode tube with a slow sputtering material applied thereto prior to application of the target material to be sputtered onto the substrate. Because the slow sputtering material is located between the cathode tube and the material to be sputtered, the likelihood of burn-through can be reduced. In certain instances, target utilization and/or lifetime may be increased. In certain other example embodiments, a non-conductive layer may be provided proximate end portion(s) of the target between the cathode tube and the target material in order to reduce or prevent sputtering of material once the target material has been sputtered off such portion(s).

This invention relates to a target for use in sputtering (e.g., magnetron sputtering). In certain example embodiments, the cathode tube of the target is coated with a slow sputtering material prior to applying the target material to the tube. Thus, the slow sputtering material is located between the tube itself and the target material. This can reduce or eliminate the risk of burn-through during sputtering, particularly in the turn around area, and/or which may increase the target utilization and/or lifetime in certain example instances.

### BACKGROUND OF THE INVENTION

Sputtering is known in the art as a technique for depositing layers or coatings onto substrates. For example, a low-emissivity (low-E) coating can be deposited onto a glass substrate by successively sputter-depositing a plurality of different layers onto the substrate. As an example, a low-E coating may include the following layers in this order: glass substrate/SnO₂/ZnO/Ag/ZnO, where the Ag layer is an IR reflecting layer and the metal oxide layers are dielectric layers. In this example, one or more tin (Sn) targets may be used to sputter-deposit the base layer of SnO₂, one or more zinc (Zn) inclusive targets may be used to sputter-deposit the next layer of ZnO, an Ag target may be used to sputter-deposit the Ag layer, and so forth. The sputtering of each target is performed in a chamber housing a gaseous atmosphere (e.g., a mixture of Ar and O gases in the Sn and/or Zn target atmosphere(s)). In each sputtering chamber, sputtering gas discharge is maintained at a partial pressure less than atmospheric.

Example references discussing sputtering and devices used therefore include U.S. Pat. Nos. 5,427,665, 5,725,746 and 2004/0163943, the entire disclosures of which are all hereby incorporated herein by reference.

A sputtering target (e.g., cylindrical rotatable magnetron sputtering target) typically includes a cathode tube within which is a magnet array. The cathode tube is often made of stainless steel. The target material is formed on the tube by spraying, casting or pressing it onto the outer surface of the stainless steel cathode tube. Each sputtering chamber includes one or more targets, and thus includes one or more of these cathode tubes. The cathode tube(s) may be held at a negative potential (e.g., −200 to −1500 V), and may be sputtered when rotating. When a target is rotating, ions from the sputtering gas discharge are accelerated into the target and dislodge, or sputter off, atoms of the target material. These atoms, in turn, together with the gas form the appropriate compound (e.g., tin oxide) that is directed to the substrate in order to form a thin film or layer of the same on the substrate.

There are different types of sputtering targets, such as planar magnetron and cylindrical rotatable magnetron targets. Planar magnetrons may have an array of magnets arranged in the form of a closed loop and mounted in a fixed position behind the target. A magnetic field in the formed of a closed loop is thus formed in front of the target. This field causes electrons from the discharge to be trapped in the field and travel in a pattern which creates a more intense ionization and higher sputtering rate. Since sputter is mainly performed in the zone defined by the magnetic field, a racetrack shaped erosion zone is produced as sputtering occurs. In other words, the target material is unevenly sputtered off of the target during sputtering in such planar magnetron targets.

Rotating magnetron targets, including the tube and target material, were developed to overcome erosion problems of planar magnetrons. In the case of rotating magnetrons, the cathode tube and target material thereon are rotated over a magnetic array (that is often stationary) that defines the sputtering zone. Due to the rotation, different portions of the target are continually presented to the sputtering zone which results in more uniform sputtering of the target material off of the tube. While rotating magnetron sputtering targets represent an improvement with respect to erosion, they can still experience uneven or non-uniform erosion of the sputtering material from the tube during sputtering—especially at the high sputtering rate areas proximate the target ends which are sometimes called turn-around areas/portions.

Unfortunately, the uneven sputtering of the target material off of the cathode tube can result in undesirable burn-through. Burning through the target material to the tube would result in the sputtering of material making up the tube (e.g., stainless steel) thereby resulting in contamination of the sputtered film on the substrate. If allowed to continue, a hole could develop in the backing tube which would allow cooling water from the tube interior to enter the sputtering chamber. Thus, it will be appreciated that burn-through represents a significant problem.

In view of the above, it will be appreciated that there exists a need in the art for a sputtering target constructed in a manner designed to reduce the likelihood of problematic burn-through.

### BRIEF SUMMARY OF EXAMPLES OF THE INVENTION

Certain example embodiments of this invention relate to a target for use in sputtering materials onto a substrate. In certain example embodiments, the target comprises a cathode tube with a slow sputtering material applied thereto prior to application of the target material to be sputtered onto the substrate. Thus, the slow sputtering material is located between the cathode tube and the material to be sputtered, with both the slow sputtering material and the material to be sputtered being supported by the cathode tube. The use of the slow sputtering material between the cathode tube and the material to be sputtered is advantageous in that this can reduce the risk of burn-through to the tube during sputtering (e.g., in the turn-around area of the target). In certain example embodiments, the use of the slow sputtering material may increase the target utilization and/or lifetime of the target.

The use of a thin layer of slow sputtering material (e.g., Ti) as a pre-coating for a cathode tube target is capable of preventing or reducing the likelihood of burn-through to or of the tube. An alternative can be to utilize the slow sputtering material as the material for making the cathode tube. In either case, target materials to be sputtered (e.g., Sn, Zn, etc.) can be applied over the slow sputtering material. When the target material to be sputtered has been consumed by sputtering, especially in the turn-around region of the cathode, the slow sputtering material can protect the target tube from burn-through. In certain example embodiments, the slow sputtering material may extend along the entire, or substantially the entire, length of the target tube, and/or is not exposed during normal sputtering operations.

In certain other example embodiments of this invention, a layer or coating of non-conductive material (e.g., an oxide of Si, Sn, Zn, etc.) provided on the cathode tube 2 (only in the dogbone section) can be used to protect against burn-through. This non-conductive material, located in the dogbone section of the target, is effective in that the etching pattern (sputtering) will slow down or substantially stop at the non-conductive material when the target material in that area is consumed since the surface charge will prevent or reduce sputtering ions such as Ar+ bombardment, especially when a DC, pulse DC or middle frequency AC power supply is used for sputtering. While this could cause an increase in micro-arcing (not big hard arcs) when the non-conductive material is exposed during sputtering, this micro-arcing should not significantly affect coating the product but instead could be advantageous in that it can give an operator a signal or indication as to how much of the target life is left (e.g., it is time to replace the target, or soon will be). In different example embodiments of this invention, the non-conductive layer can be applied either only in the dogbone section, or alternatively over the entire length of the target tube (e.g., when an rf power supply is used for puttering).

### BRIEF DESCRIPTION OF THE DRAWINGS

FIG. 1 is a perspective view of a sputtering target according to an example embodiment of this invention.

FIG. 2 is a cross sectional view of a part of the sputtering target of FIG. 1.

FIG. 3 is a perspective view of a sputtering apparatus using the target of FIGS. 1-2 (or FIG. 4), according to an example embodiment of this invention.

FIG. 4 is a perspective view of a sputtering target according to another example embodiment of this invention.

### DETAILED DESCRIPTION OF EXAMPLE EMBODIMENTS OF THE INVENTION

Referring now more particularly to the accompanying drawings in which like reference numerals indicate like parts throughout the several views.

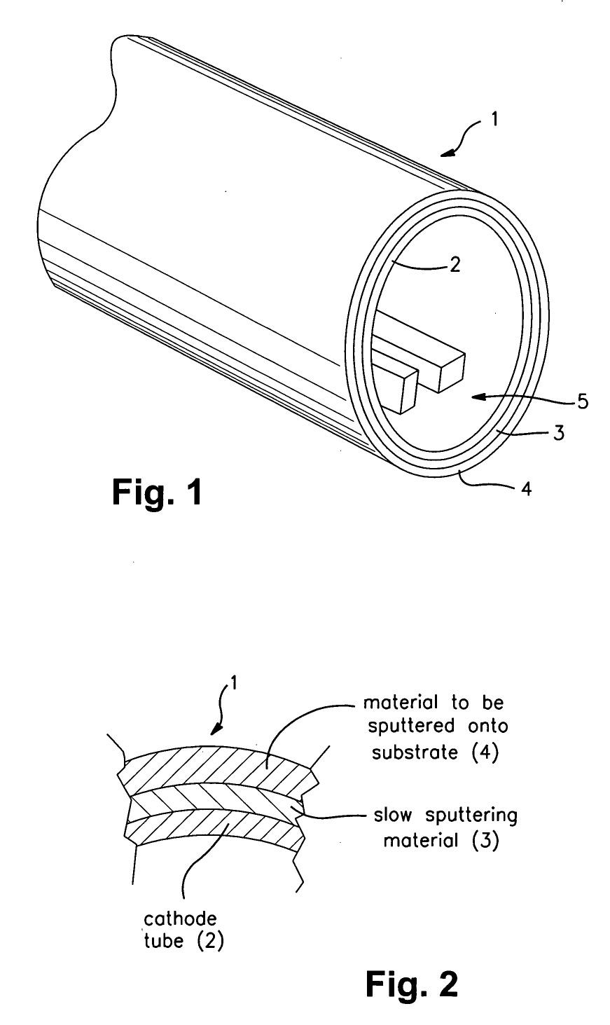

FIGS. 1-2 illustrate an example sputtering target according to an example non-limiting embodiment of this invention, with FIG. 2 being a cross-sectional view of a part of the target of FIG. 1. The illustrated cylindrical rotating target 1 includes a cathode tube 2 with a slow sputtering material 3 applied thereto prior to application of the target material 4 to be sputtered onto the substrate. Thus, the slow sputtering material 3 is on the tube 2, and is located between the cathode tube 2 and the target material 4 to be sputtered. Both the slow sputtering material 3 and the material 4 to be sputtered are on and supported by the cathode tube 2. Materials 3 and 4 may be formed on the tube 2 in any suitable manner (e.g., via plasma spraying). The use of the slow sputtering material 3 between the cathode tube 2 and the material 4 to be sputtered is advantageous in that this can reduce the risk of burn-through to, or of, the tube 2 during sputtering (e.g., especially in or near the turn-around area of the target). In certain example embodiments, the target's lifetime and/or utilization may also be increased through the use of the slow sputtering material.

Example slow-sputtering materials that may be used for layer 3 include Ti, W, Nb, Ta, and so forth. Example target materials that may be used for target material layer 4 include, Sn, Zn and the like. In certain example embodiments, the slow sputtering material has both mechanical durability and good adhesion to both the cathode tube and the sputtering/target material. Generally speaking, the material of target material layer 4 has a faster sputtering rate than does the material of layer 3 in certain example embodiments of this invention.

Layers 3 and 4 are both conductive in certain example embodiments of this invention. However, in other example embodiments, ceramic material may be used for layer 3 and/or layer 4.

The provision of magnet array 5, which is typically stationary even when the tube 2 (and layers 3, 4 thereon) is rotating, inside the tube causes the target material to be sputtered unevenly in certain areas. This can result in burn-through, for example in an area where the sputtering rate of the target material is unusually fast. The provision of material 3 is designed to prevent or reduce the likelihood of such burn-through.

Hollow cathode tubes 2 are generally made of stainless steel. Burning through a target material 4 would sputter material from the backing tube 2, resulting in contamination of the sputtered film being deposited on the substrate. If allowed to continue, a hole could develop in the backing tube 2 which would allow cooling water to enter the chamber; this would damage the product being made and/or sputtering apparatus. Thus, in certain example embodiments, the slow sputter material layer 3 has a thickness of at least about 1 mm (more preferably from about 1-8 mm) thick to provide integrity. Typically, the thickness of the target material layer 4 is from about 3 to 25 mm, more preferably from about 6 to 16 mm.

In other example embodiments of this invention, an alternative is to utilize the slow sputtering material 3 as the material for making the cathode tube. In such an embodiment, the cathode tube would not be made of stainless steel, but instead would be made of a slow sputter material such as Ti, W, Nb, Ta, or the like. In either case, target materials 4 to be sputtered (e.g., Sn, Zn, etc.) can be applied over the slow sputtering material 3. When the target material 4 to be sputtered has been consumed by sputtering, especially in the turn-around region of the cathode, the slow sputtering material can protect the target tube from burn-through. In certain example embodiments, the slow sputtering material may extend along the entire, or substantially the entire, length of the target tube 2, and/or is not exposed during normal sputtering operations.

FIG. 4 illustrates a sputtering target according to another example embodiment of this invention. In the FIG. 4 embodiment, a layer or coating 8 of non-conductive material (e.g., an oxide of Si, Sn, Zn, etc.) is provided on the cathode tube 2 (only in the dogbone or racetrack section proximate the end(s) of the tube, e.g., when DC, pulse DC or middle frequency AC sputtering is used). In RF sputtering embodiments, the dielectric material 8 may be applied to substantially only the dogbone section, or alternatively along the entire tube length since there is no conductivity requirement for the target material. This non-conductive material 8 is provided between the cathode tube 2 and the target material 4, and is used to protect against burn-through. Non-conductive material 8, located in the racetrack or dogbone section of the target near the end(s) thereof, is effective in that the etching pattern (sputtering) will slow down or substantially stop at the non-conductive material 8 when the target material 4 in that area has been consumed (sputtered off) since the surface charge will prevent or substantially reduce sputtering ion (e.g., Ar+) bombardment. This is also advantageous in that it will reduce contamination of the film being sputtered onto the substrate. While the use of such non-conductive 8 material under a conductive target material could cause an increase in micro-arcing (not big hard arcs) when the non-conductive material is exposed during sputtering, this micro-arcing should not significantly affect coating the product but instead could be advantageous in that it can give an operator a signal or indication as to how much of the target life is left (e.g., it is time to replace the target, or soon will be).

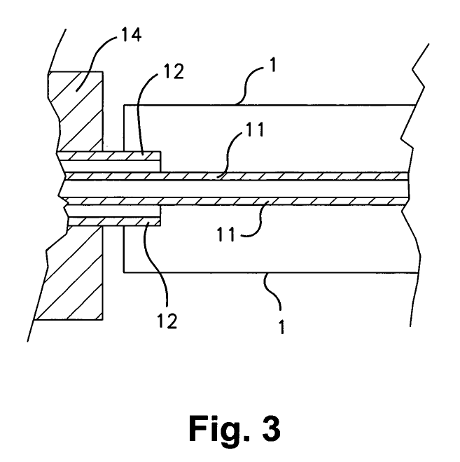

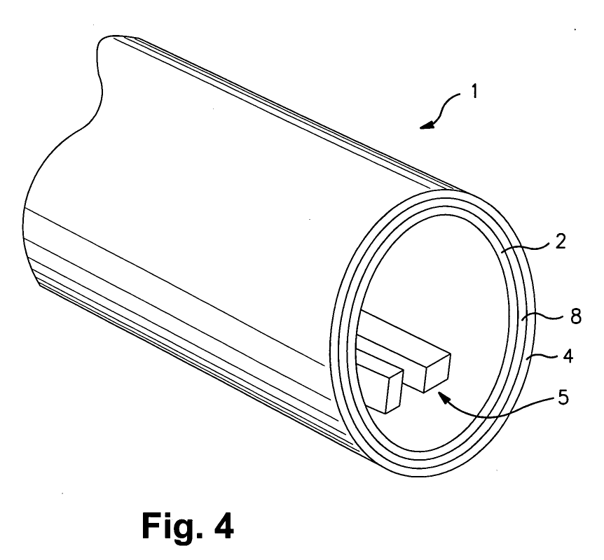

FIG. 3 is a cross sectional view of a sputtering apparatus that can use the target 1 of FIGS. 1-2 or 4. The sputtering apparatus includes cooling tubes 11, 12 through which cooling fluid (e.g., water) flows in order to cool the target and/or magnets during sputtering operations. The target 1 is rotatably mounted to support 14 so that during sputtering operations the target 1 rotates relative to the support 14. Shields (not shown) may also be provided in a known manner.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A sputtering target comprising:
a rotatable cathode tube housing at least one magnet therein;
a slow sputtering layer provided on an outer surface of the cathode tube along at least a substantial portion of the length of the cathode tube;
a target material layer provided on the outer surface of the cathode tube over at least the slow sputtering layer; and
wherein the slow sputtering layer has a sputter rate less than that of the target material layer.

2. The sputtering target of claim 1, wherein the cathode tube is made of stainless steel.

3. The sputtering target of claim 1, wherein the target material layer comprises one or more of Sn and Zn, and wherein the slow sputtering layer comprises one or more of Ti, W, Nb and Ta.

4. The sputtering target of claim 1, wherein the slow sputtering layer directly contacts each of the cathode tube and the target material layer.

5. The sputtering target of claim 1, wherein the slow sputtering layer has a thickness of from about 1-8 mm, and the target material layer has a thickness of from about 6-16 mm.

6. The sputtering target of claim 1, wherein the slow sputtering layer is not exposed to sputtering ions during normal sputtering operations since it is adapted to be covered by at least the target material layer.

7. The sputtering target of claim 1, wherein each of the slow sputtering layer and the target material layer are electrically conductive.

8. A sputtering target comprising:
a rotatable cathode tube housing at least one magnet therein, wherein the rotatable cathode tube is made of a slow sputtering material layer and not stainless steel;
a target material layer provided on the outer surface of the cathode tube; and
wherein the cathode tube has a sputter rate less than that of the target material layer.

9. The sputtering target of claim 8, wherein the target material layer comprises one or more of Sn and Zn, and wherein the cathode tube comprises one or more of Ti, W, Nb, and Ta.

10. The sputtering target of claim 8, wherein the target material layer directly contacts an outer surface of the cathode tube, and wherein no conductive layer is provided on the interior surface of the cathode tube.

11. The sputtering target of claim 8, wherein the cathode tube has a thickness of from about 2-15 mm, and the target material layer has a thickness of from about 6-16 mm.

12. The sputtering target of claim 8, wherein the cathode tube is not exposed to sputtering ions during normal sputtering operations since it is adapted to be covered by at least the target material layer.

13. The sputtering target of claim 8, wherein each of the cathode tube and the target material layer are electrically conductive.

14. A sputtering target comprising:
a conductive rotatable cathode tube housing at least one magnet therein;
a non-conductive layer provided on an outer surface of the cathode tube along only a relatively small portion of the length of the length of the cathode tube;
a target material layer provided on the outer surface of the cathode tube over at least the non-conductive layer.

15. The sputtering target of claim 14, wherein the non-conductive layer comprises oxide of silicon and/or metal oxide.

16. The sputtering target of claim 14, wherein the non-conductive layer comprises a dielectric material that is not conductive.

17. The sputtering target of claim 14, wherein the non-conductive layer is provided only proximate one or both end portions of the cathode tube, and is not provided in a central portion along the length of the cathode tube.

18. The sputtering target of claim 14, wherein the non-conductive layer is adapted to reduce or prevent sputtering of material from the target in area(s) where the non-conductive layer is present when the target material has been sputtered off of said area(s).

19. The sputtering target of claim 1, wherein one or both of the slow sputtering layer and the target material layer is/are non-conductive.
